(19) United States
(12) Patent Application Publication
(10) Pub. No.: US 2024/0355668 A1
(43) Pub. Date: Oct. 24, 2024

(54) SEMICONDUCTOR APPARATUS, SEMICONDUCTOR APPARATUS MANUFACTURING METHOD, AND X-RAY COMPUTED TOMOGRAPHY APPARATUS

(71) Applicant: CANON MEDICAL SYSTEMS CORPORATION, Otawara-shi (JP)

(72) Inventors: Tatsuya SUZUKI, Kokubunji (JP); Nobuhiko SATO, Yokohama (JP)

(73) Assignee: CANON MEDICAL SYSTEMS CORPORATION, Otawara-shi (JP)

(21) Appl. No.: 18/637,949

(22) Filed: Apr. 17, 2024

(30) Foreign Application Priority Data
Apr. 21, 2023 (JP) 2023-069942

(51) Int. Cl. H01L 21/70; H01L 21/02; H01L 21/28; H01L 21/8234

(52) U.S. Cl. CPC H01L 21/707; H01L 21/0214; H01L 21/0228; H01L 21/28202; H01L 21/823475

(57) ABSTRACT

A semiconductor apparatus according to an embodiment of the present disclosure includes: a substrate; a wiring layer serving as a topmost layer formed over the substrate; a first protection film formed so as to cover the wiring layer; a planarization film formed on the first protection film; and a second protection film formed on the planarization film. The first protection film and the second protection film are each thicker than the planarization film.

### CROSS-REFERENCE TO RELATED APPLICATIONS

This application is based upon and claims the benefit of priority from Japanese Patent Application No. 2023-069942, filed on Apr. 21, 2023; the entire contents of which are incorporated herein by reference.

### FIELD

Embodiments described herein relate generally to a semiconductor apparatus, a semiconductor apparatus manufacturing method, and an X-ray computed tomography apparatus.

### BACKGROUND

A semiconductor apparatus including a wiring layer provided over a substrate and a protection film provided for protecting the wiring layer is known.

During a mounting process, pressure may concentrate on the protection film provided over the wiring layer, and the protection film may be cracked by pressure occurring when an unwanted substance has entered in-between. In the event such a crack reaches the wiring layer, corrosion of the wiring layer may be accelerated, depending on the environment of use.

### BRIEF DESCRIPTION OF THE DRAWINGS

FIG. 1 is a cross-sectional view illustrating a configuration of a semiconductor apparatus according to a comparison example;

FIG. 2 is a cross-sectional view illustrating a configuration of a semiconductor apparatus according to a first embodiment;

FIG. 3 is a drawing illustrating exemplary configurations of protection films according to the first embodiment;

FIG. 4 is a flowchart illustrating a method for manufacturing the semiconductor apparatus according to the first embodiment;

FIG. 5 is a process cross-sectional view illustrating the method for manufacturing the semiconductor apparatus according to the first embodiment;

FIG. 6 is another process cross-sectional view illustrating the method for manufacturing the semiconductor apparatus according to the first embodiment;

FIG. 7 is yet another process cross-sectional view illustrating the method for manufacturing the semiconductor apparatus according to the first embodiment;

FIG. 8 is yet another process cross-sectional view illustrating the method for manufacturing the semiconductor apparatus according to the first embodiment;

FIG. 9 is yet another process cross-sectional view illustrating the method for manufacturing the semiconductor apparatus according to the first embodiment;

FIG. 10 is yet another process cross-sectional view illustrating the method for manufacturing the semiconductor apparatus according to the first embodiment;

FIG. 11 is yet another process cross-sectional view illustrating the method for manufacturing the semiconductor apparatus according to the first embodiment;

FIG. 12 is a cross-sectional view illustrating an example of a semiconductor apparatus used in an X-ray computed tomography apparatus;

FIG. 13 is a cross-sectional view illustrating a configuration of a semiconductor apparatus according to a second embodiment;

FIG. 14 is a flowchart illustrating a method for manufacturing the semiconductor apparatus according to the second embodiment; and

FIG. 15 is a diagram illustrating an exemplary configuration of an X-ray computed tomography apparatus according to a third embodiment.

### DETAILED DESCRIPTION

A semiconductor apparatus according to an embodiment of the present disclosure includes: a substrate; a wiring layer serving as a topmost layer formed over the substrate; a first protection film formed so as to cover the wiring layer; a planarization film formed on the first protection film; and a second protection film formed on the planarization film. The first protection film and the second protection film are each thicker than the planarization film.

Exemplary embodiments of the present disclosure will be explained below, with reference to the accompanying drawings. In the following description and the drawings, two or more of the drawings may be referenced by each other. Some of the elements appearing in common to two or more of the drawings will be referred to by using the same reference characters. Explanations of those elements having the same reference characters will be omitted as appropriate.

Further, a same element may be depicted in different sizes or scales in different drawings. Furthermore, from a viewpoint of ensuring legibility of the drawings, for example, reference characters may be appended only to principal or representative constituent elements in the description of the drawings. In addition, some of the constituent elements having the same or substantially the same functions may not have reference characters in some situations.

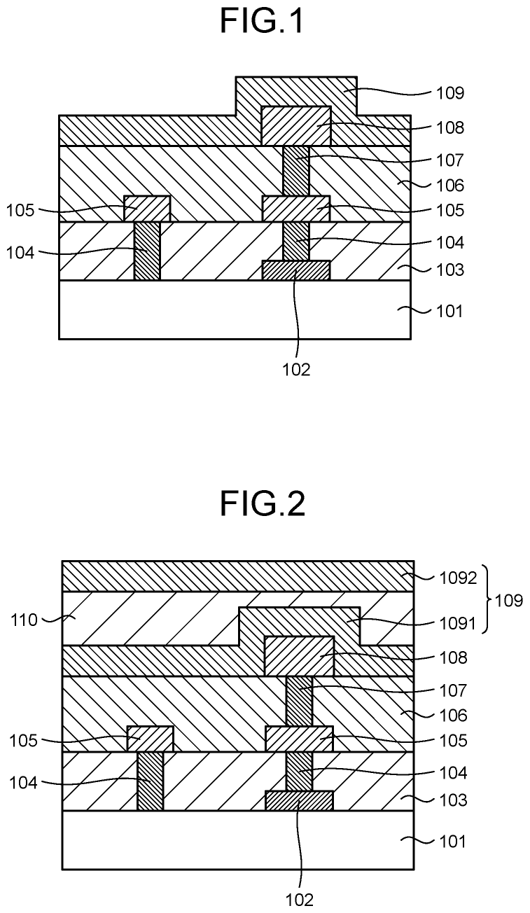

FIG. 1 is a cross-sectional view schematically illustrating a configuration of a semiconductor apparatus according to a comparison example. The semiconductor apparatus illustrated in FIG. 1 includes: a silicon substrate 101 being a semiconductor substrate provided with a Metal-Oxide-Semiconductor-Field-Effect transistor (MOS transistor) 102 and an interlayer insulation film 103; and a wiring layer 108 provided over the silicon substrate while the interlayer insulation film 103 is interposed therebetween. The wiring layer 108 is covered by the interlayer insulation film 103 and a protection film 109.

### First Embodiment

FIG. 2 is a cross-sectional view illustrating a configuration of a semiconductor apparatus according to a first embodiment. The semiconductor apparatus includes the silicon substrate 101, the MOS transistor 102, the interlayer insulation film 103, a contact 104, a wiring layer 105, an interlayer insulation film 106, vias 107, the wiring layer 108, protection films 109 (a first protection film 1091 and a second protection film 1092), and a planarization film 110. Instead of being the silicon substrate, the semiconductor substrate may be a chemical compound semiconductor substrate using gallium phosphide (GaP), gallium arsenide (GaAs), indium phosphide (InP), gallium nitride (GaN), or the like or may be a silicon carbide (SiC) substrate or a sapphire substrate.

The MOS transistor 102, the interlayer insulation film 103, and the contact 104 are formed on the silicon substrate 101. The wiring layer 105, the interlayer insulation film 106, and the vias 107 are formed on the interlayer insulation film 103. The wiring layer 108 is formed over the silicon substrate 101. Also, the wiring layer 108 is formed over the interlayer insulation film 106. The first protection film 1091 is formed so as to cover the wiring layer 108. The planarization film 110 is formed on the first protection film 1091. The second protection film 1092 is formed on the planarization film 110.

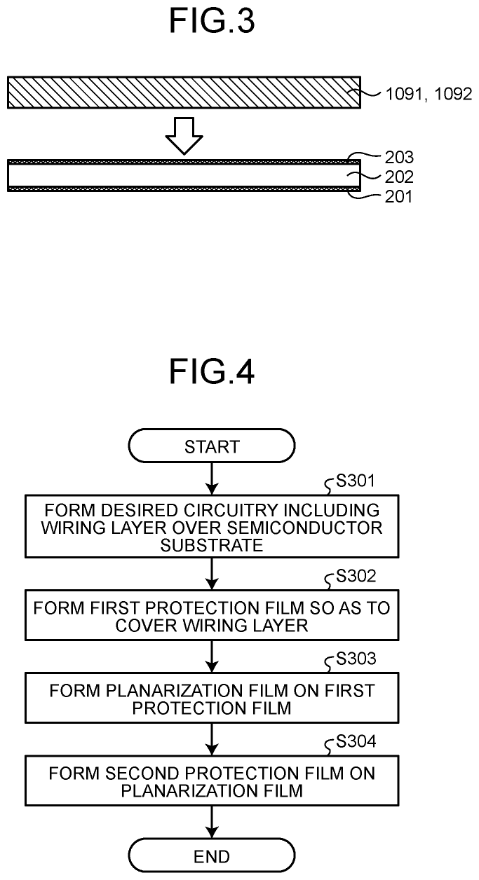

FIG. 3 illustrates an exemplary configuration of each of the first protection film 1091 and the second protection film 1092 according to the present embodiment. The first protection film 1091 and the second protection film 1092 of the present embodiment may have mutually the same structure. Thus, FIG. 3 is based on the assumption that the first protection film 1091 and the second protection film 1092 have mutually the same structure. The first protection film 1091 and the second protection film 1092 of the present embodiment each have a three-layer structure.

The first protection film 1091 and the second protection film 1092 each include, for example, a silicon oxynitride film 201, a silicon nitride film 202, and another silicon oxynitride film 203. The silicon oxynitride film 201 and the silicon oxynitride film 203 are used as anti-reflection films. By using an anti-reflection structure described herein, it is possible to enhance a transmittance rate of incident light and to thus enhance sensitivity. With the first protection film 1091 and the second protection film 1092 each configured in this manner, it is possible to ensure reliability of the semiconductor apparatus by preventing infiltration of moisture, impurities, and the like from the outside.

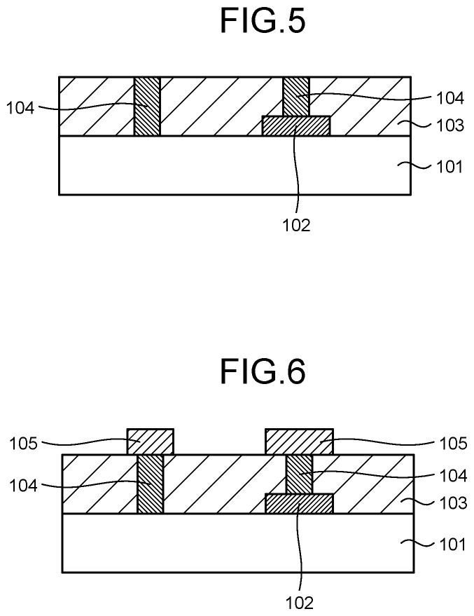

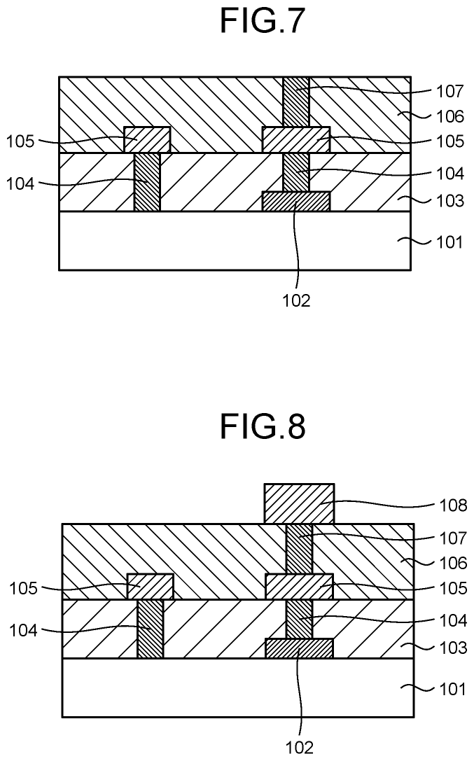

FIG. 4 is a flowchart illustrating a method for manufacturing the semiconductor apparatus according to the present embodiment. Further, FIGS. 5 to 11 are process cross-sectional views illustrating the method for manufacturing the semiconductor apparatus according to the present embodiment.

At step S301, as illustrated in FIGS. 5 to 8, on the silicon substrate 101 of the semiconductor apparatus, the MOS transistor 102, the interlayer insulation film 103, and the contact 104 are formed. Further, on the interlayer insulation film 103, the wiring layer 105, the interlayer insulation film 106, and the vias 107 are formed. In addition, the wiring layer 108 is formed on the interlayer insulation film 106.

As the wiring layer 105 and the wiring layer 108, for example, aluminum, copper, or an alloy film of the two may be used. As the contact 104 and the vias 107, a metal film of tungsten, titanium nitride, titanium, or the like or a layered structure of any of these may be used. For example, used as the interlayer insulation film 103 may be a silicon oxide film formed with Non-Doped Silicate Glass (NSG) or Boron-Phospho Silicate Glass (BPSG) by implementing a Chemical Vapor Deposition (CVD) method. For example, used as the interlayer insulation film 106 may be a silicon oxide film formed by implementing a plasma CVD method.

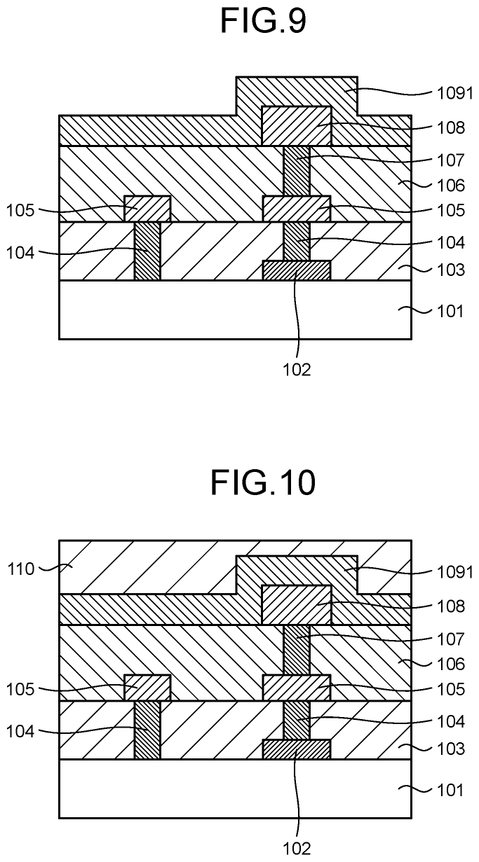

At step S302, as illustrated in FIG. 9, the first protection film 1091 is formed so as to cover the wiring layer 108. The protection films 109 (the first protection film 1091 and the second protection film 1092 (explained later)) are insulation films for protecting internal elements from an environment of use. For example, it is possible to use films each serving as a protection film (a passivation film) structured with a silicon nitride film, a silicon oxide film, a silicon oxynitride film, or the like.

The silicon nitride film, the silicon oxide film, and the silicon oxynitride film described above are formed by implementing a plasma CVD method. The film thickness of each of the first protection film 1091 and the second protection film 1092 formed with any of those films is in the range from 420 nm to 700 nm, for example.

At step S303, as illustrated in FIG. 10, the planarization film 110 is formed on the first protection film 1091. The planarization film 110 is provided so as to planarize unevenness formed on the first protection film 1091. The planarization film 110 is a film formed by implementing a plasma CVD method and, for example, a silicon oxide film may be used in the present embodiment. The thickness of the planarization film 110 from the first protection film 1091 to the second protection film 1092 (explained later) provided on the wiring layer 108 is in the range from 100 nm to 400 nm.

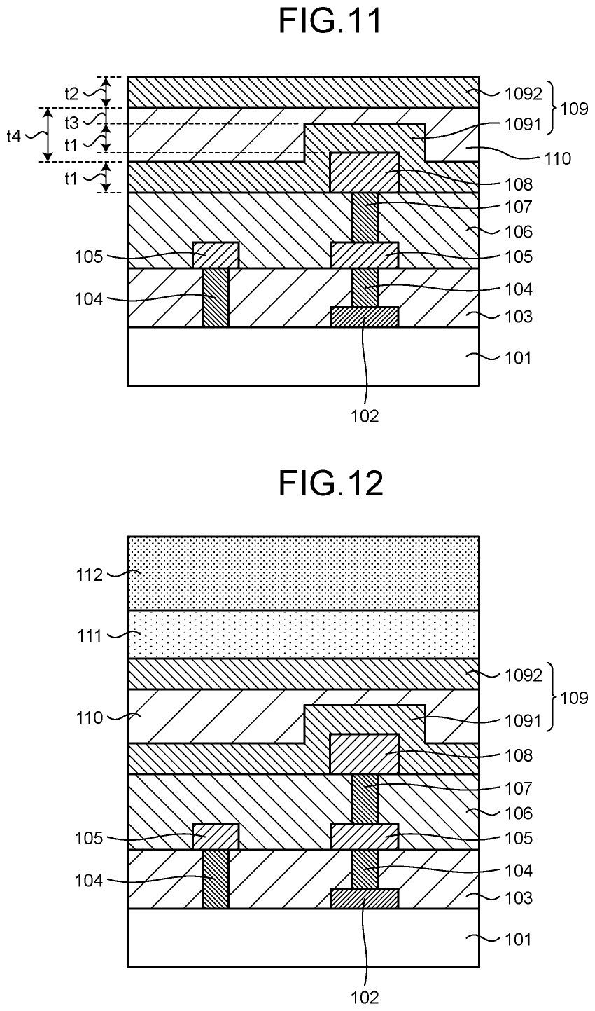

At step S304, as illustrated in FIG. 11, the second protection film 1092 is formed on the planarization film 110. Similarly to the first protection film 1091, the second protection film 1092 is a film formed by implementing a plasma CVD method and, for example, a protection film (a passivation film) structured with a silicon nitride film, a silicon oxide film, a silicon oxynitride film, or the like, may be used in the present embodiment. The thickness of the second protection film 1092 is in the range from 420 nm to 700 nm. In other words, the first protection film 1091 and the second protection film 1092 are each thicker than the planarization film 110.

Further, FIG. 11 indicates the thicknesses of the plurality of films as t1, t2, t3, and t4. The thickness t1 denotes the thickness of the first protection film 1091, which is in the range from 420 nm to 700 nm. The thickness t2 denotes the thickness of the second protection film 1092, which is in the range from 420 nm to 700 nm. The thickness t3 denotes the thickness of a part of the planarization film 110 positioned over the wiring layer 108 and is in the range from 100 nm to 400 nm. The thickness t4 denotes the thickness of the part of the planarization film 110 that does not overlap with the wiring layer 108 in a top view of the silicon substrate 101.

The thickness t4 of the abovementioned part may be larger than the thickness of the first protection film 1091 or the second protection film 1092; however, the thickness t1 and the thickness t2 may each be larger than the thickness t4. In a planarization process performed after the planarization film 110 is formed, the part of the planarization film 110 positioned over the wiring layer 108 is shaved more than the part thereof that does not overlap with the wiring layer 108 in a top view of the silicon substrate 101.

As a result, the part of the planarization film 110 positioned over the wiring layer 108 and the part thereof that does not overlap with the wiring layer 108 in a top view of the silicon substrate 101 are formed as a plane that is continuously flat. In the present embodiment, the thickness t1 of the first protection film 1091 and the thickness t2 of the second protection film 1092 are larger than the thickness t3 of the part of the planarization film 110 positioned over the wiring layer 108. Further, by ensuring that the thickness t1 and the thickness t2 are each larger than the thickness t3 by 50 nm or more, it is possible to provide stronger protection for the wiring layer 108.

As a result of the processes at steps S301 through S304 described above, the semiconductor apparatus (an Integrated Circuit (IC) chip) of the present embodiment is manufactured.

Next, effects of the present embodiment will be explained. Generally speaking, protection films provided over a wiring layer are formed by implementing a plasma CVD method at a low temperature such as 400° C. or lower, so that the wiring layer does not melt in heat treatment. For this reason, the strength of the protection films is lower than the strength that might be achieved if heat treatment were performed at a high temperature.

During a mounting process in which a semiconductor apparatus (an Integrated Circuit (IC) chip) is pressure-bonded onto a ceramic substrate or the like, when pressure applied to the semiconductor apparatus by an apparatus used in the mounting process (e.g., a backgrinding process, a dicing process, and/or a die bonding process) imposes a concentrated load on a protection film provided on a wiring layer or in the event that an unwanted substance enters between the apparatus used in the mounting process and the semiconductor apparatus so that the semiconductor apparatus comes under pressure caused by the unwanted substance caught in-between, the protection film serving as a top layer of the semiconductor apparatus may be cracked, and long-term reliability of the semiconductor apparatus may thereby be degraded.

For instance, during the backgrinding process, the structure illustrated in FIG. 1 is fixed to a base of an apparatus performing the backgrinding process by an adhesive tape pasted on a top part of the protection film 109. Further, by polishing the rear face side of the silicon substrate 101, the thickness of the silicon substrate 101 is reduced. At the time of polishing the silicon substrate 101, a concentrated load may be imposed on the protection film 109 on which the adhesive tape is pasted. As a result, the protection film 109 may be cracked, which makes the protection for the wiring layer 108 insufficient.

In contrast, provided in the present embodiment are: the first protection film 1091 formed so as to cover the wiring layer serving as the topmost layer; the planarization film 110 formed on the first protection film; and the second protection film 1092 formed on the planarization film 110. The protection films 109 are the silicon nitride films having an excellent waterproof property and are each provided with a thickness in the range from 420 nm to 700 nm which is sufficiently thicker than that of the planarization film 110. Thus, even when the second protection film 1092 is cracked, it is possible to stop the crack within the protection films 109 so as not to reach the wiring layer 108 and to thus prevent the wiring layer from being corroded.

Further, from an indentation hardness evaluation based on a nanoindentation scheme, it was observed that, even with the same thickness, providing the insulation film with an interface by using a combination of the planarization film and the protection films is able to exert a higher effect against an indentation load than using a sufficiently thick single-layer protection film.

In addition, by configuring the semiconductor apparatus according to the present embodiment so that, as illustrated in FIG. 12, the semiconductor apparatus is provided with an Optical Clear Adhesive (OCA) sheet 111 and a scintillator 112, it is possible to structure an imaging apparatus which is capable of acquiring an image visualizing strengths of radiation and which can be employed in an X-ray CT detector used in an X-ray computed tomography apparatus. In that situation, the timing when the semiconductor apparatus comes under pressure is before the optical clear adhesive sheet 111 and the scintillator 112 are used.

As explained above, the semiconductor apparatus is configured to include: the first protection film 1091 that is formed, with respect to the wiring layer serving as the topmost layer formed over the substrate, so as to cover the wiring layer; the planarization film 110 formed on the first protection film 1091; and the second protection film 1092 formed on the planarization film, while the first protection film 1091 and the second protection film 1092 are each thicker than the planarization film. As a result, it is possible to enhance resistance against cracks and to prevent the wiring layer from being corroded.

As explained above, the semiconductor apparatus according to the present embodiment includes: the substrate; the wiring layer serving as the topmost layer formed over the substrate; the first protection film formed so as to cover the wiring layer; the planarization film formed on the first protection film; and the second protection film formed on the planarization film, while the first protection film and the second protection film are each thicker than the planarization film.

According to the present embodiment, because the configuration is provided with the wiring layer serving as the topmost layer formed over the substrate, the first protection film formed so as to cover the wiring layer, the planarization film formed on the first protection film, and the second protection film formed on the planarization film, it is possible to prevent the wiring layer from being corroded.

Further, the present embodiment is more effective on structures having a large photodiode area and a low wiring density in a semiconductor apparatus, such as a semiconductor apparatus mounted on an X-ray CT detector.

Further, it is possible to carry out the embodiment described above with an appropriate modification, by changing a part of the configuration or the functions of the semiconductor apparatus. Thus, in the following sections, a number of modification examples of the above embodiment will be explained as other embodiments. In the following sections, differences from the above embodiment will primarily be explained. Some of the elements that are the same as those previously explained will be referred to by using the same reference characters, and detailed explanations thereof will be omitted. Further, the other embodiments described below may be carried out individually or may be carried out in combination as appropriate.

### Second Embodiment

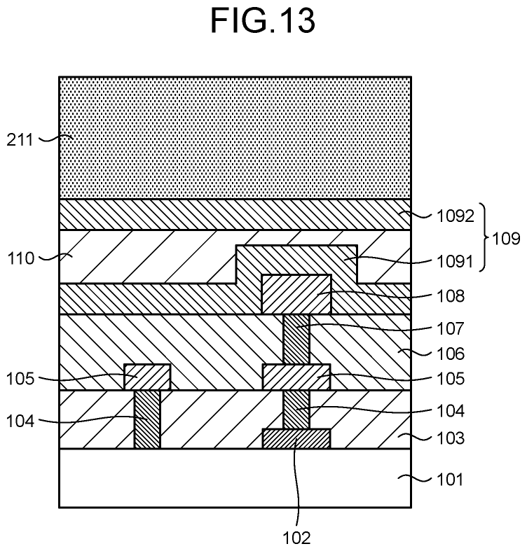

Next, a second embodiment of the present disclosure will be explained with reference to FIG. 13. FIG. 13 is a cross-sectional view illustrating a configuration of a semiconductor apparatus according to the second embodiment. The second embodiment has a configuration similar to that of the semiconductor apparatus according to the first embodiment. Some of the elements that are the same will be referred to by using the same reference characters, and explanations thereof will be omitted. In the semiconductor apparatus according to the second embodiment, as illustrated in FIG. 13, an organic film 211 may be used on the second protection film 1092.

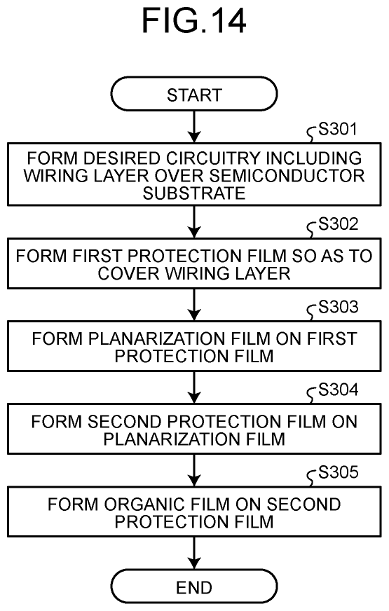

FIG. 14 is a flowchart illustrating a method for manufacturing the semiconductor apparatus according to the second embodiment. Because steps S301 through S304 in FIG. 14 are the same as steps S301 through S304 in FIG. 4, detailed explanations thereof will be omitted.

At step S305, as illustrated in FIG. 13, the organic film 211 is formed on the second protection film 1092. The organic film 211 is an organic material-based film using an organic material. In the present embodiment, at least one layer of the organic material-based film is formed so as to have a thickness in the range of approximately 1 μm to 3 μm.

Further, similarly to the example in FIG. 12 according to the first embodiment, by using a configuration in which the optical clear adhesive sheet 111 is provided on the organic film 211, while the scintillator 112 is provided on the optical clear adhesive sheet 111, it is possible to obtain an X-ray computed tomography apparatus employing this structure as an X-ray detector thereof. In this situation, the timing when the semiconductor apparatus comes under pressure is before the optical clear adhesive sheet 111 and the scintillator 112 are used, similarly to the first embodiment.

As explained above, the semiconductor apparatus is configured to include: the first protection film that is formed, with respect to the wiring layer serving as the topmost layer formed over the substrate, so as to cover the wiring layer; the planarization film formed on the first protection film; the second protection film formed on the planarization film; and the organic film formed on the second protection film, while the protection films and the organic film are each sufficiently thicker than the planarization film. As a result, it is possible to enhance resistance against cracks. In addition, in the situation where the semiconductor apparatus is used with the optical clear adhesive sheet 111 and the scintillator 112, it is also possible to enhance adhesion with the optical clear adhesive sheet 111.

### Third Embodiment

Next, an embodiment will be explained in which the semiconductor apparatus according to the first or the second embodiment is applied to an X-ray detector included in an X-ray computed tomography apparatus.

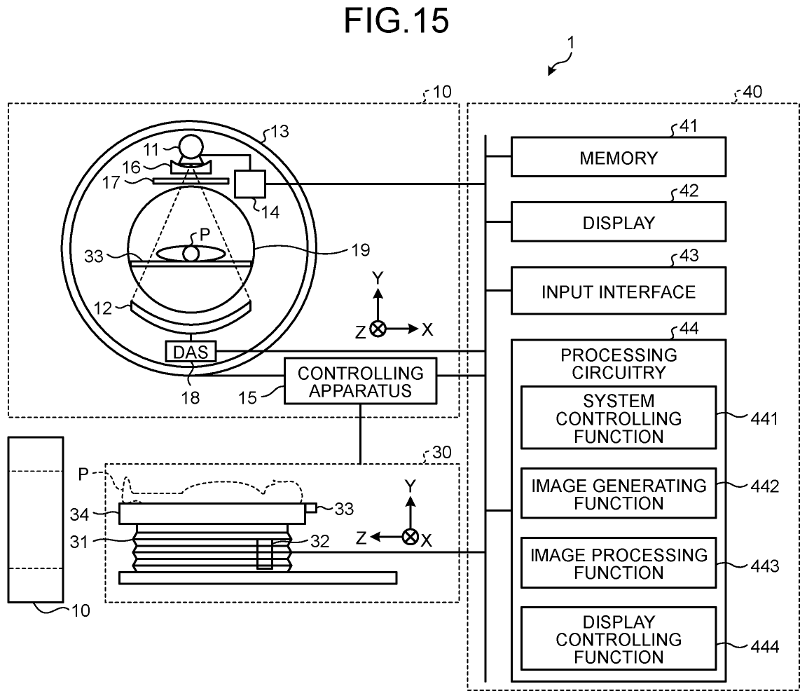

FIG. 15 is a diagram illustrating an exemplary configuration of an X-ray computed tomography apparatus 1. As illustrated in FIG. 15, the X-ray computed tomography apparatus 1 includes a gantry 10, a table 30, and a console 40. It should be noted that FIG. 15 depicts the gantry 10 in multiple locations for the sake of convenience in the explanations. The gantry 10 is a scan apparatus having a configuration used for performing X-ray CT imaging on an examined subject (hereinafter, “patient”) P. The table 30 is a conveyance apparatus on which the patient P undergoing the X-ray CT imaging is placed and which is used for determining the position of the patient P.

The console 40 is a computer configured to control the gantry 10 and the table 30. For example, the gantry 10 and the table 30 may be provided in a CT examination room, whereas the console 40 may be provided in a control room adjacent to the CT examination room. The gantry 10, the table 30, and the console 40 are communicably connected to one another in a wired or wireless manner.

In this situation, the console 40 does not necessarily need to be provided in the control room. For example, the console 40 may be provided together in the same room as the gantry 10 and the table 30. Alternatively, the console 40 may be incorporated in the gantry 10.

In the present embodiment, either a rotation axis of a rotating frame 13 in a non-tilt state or the longitudinal direction of a tabletop 33 of the table 30 is defined as a Z-axis direction; the axial direction orthogonal to the Z-axis direction and parallel to a floor surface is defined as an X-axis direction; and the axial direction orthogonal to the Z-axis direction and perpendicular to the floor surface is defined as a Y-axis direction.

As illustrated in FIG. 15, the gantry 10 includes an X-ray tube 11, an X-ray detector 12, the rotating frame 13, an X-ray high-voltage apparatus 14, a controlling apparatus 15, a wedge 16, a collimator 17, and data acquisition circuitry (a Data Acquisition System (DAS)) 18.

The X-ray tube 11 is a vacuum tube having a negative pole (a filament) configured to generate thermo electrons and a positive pole (a target) configured to generate X-rays in response to collision of thermo electrons thereon. The X-ray tube 11 is configured to emit X-rays onto the patient P, by causing the thermo electrons to be emitted from the negative pole toward the positive pole, by using high voltage supplied from the X-ray high-voltage apparatus 14.

In this situation, the hardware used for generating the X-rays is not limited to the X-ray tube 11. For example, in place of the X-ray tube 11, it is also acceptable to generate the X-rays by using a fifth generation scheme. The fifth generation scheme includes: a focus coil configured to converge electron beams generated from an electron gun; a deflection coil that causes an electromagnetic deflection; and a target ring that is in a semicircle form surrounding the patient P and is configured to generate X-rays in response to collision of the electron beams being deflected.

The X-ray detector 12 is configured to detect the X-rays that were emitted from the X-ray tube 11 and have passed through the patient P and is configured to output an electrical signal corresponding to a detected X-ray amount to the data acquisition circuitry 18. The X-ray detector 12 includes, for example, arrays of X-ray detecting elements in each of which a plurality of X-ray detecting elements are arranged in a channel direction along an arc centered on a focal point of the X-ray tube 11.

For example, the X-ray detector 12 has a structure in which, while each array has the plurality of X-ray detecting elements arranged in the channel direction, the plurality of arrays are arranged in a slice direction (i.e., a row direction). Further, for example, the X-ray detector 12 may be an indirect conversion-type detector including a grid, a scintillator array, and an optical sensor array. The scintillator array includes a plurality of scintillators. Each of the scintillators includes a scintillator crystal that outputs light in a photon quantity corresponding to the amount of X-rays that have become incident thereto. The grid is arranged on a surface of the scintillator array positioned on the X-ray incident side and includes an X-ray blocking board having a function of absorbing scattered X-rays.

In the X-ray detector 12, the semiconductor apparatus according to the first or the second embodiment described above is employed as each of the X-ray detecting elements. For example, the X-ray detector 12 includes: a substrate; the wiring layer 105 formed over the substrate; the first protection film 1091 formed so as to cover the wiring layer 105; the planarization film 110 formed on the first protection film; and the second protection film 1092 formed on the planarization film, while the first protection film 1091 and the second protection film 1092 are each thicker than the planarization film 110.

Further, the grid may be referred to as a collimator (a one-dimensional collimator or a two-dimensional collimator). The optical sensor array has a function of converting the amounts of light from the scintillators into corresponding electrical signals. As optical sensors, photomultiplier tubes (PMTs) may be used, for example. Alternatively, the X-ray detector 12 may be a direct conversion-type detector including semiconductor elements configured to convert incident X-rays into electrical signals. The X-ray detector 12 is an example of a detecting unit.

The rotating frame 13 is an annular frame configured to support the X-ray tube 11 and the X-ray detector 12 so as to oppose each other and to cause the controlling apparatus 15 (explained later) to rotate the X-ray tube 11 and the X-ray detector 12. A Field of View (FOV) is set at an opening part 19 of the rotating frame 13. For example, the rotating frame 13 is cast by using aluminum as a material thereof.

In addition to the X-ray tube 11 and the X-ray detector 12, the rotating frame 13 may be configured to further support the X-ray high-voltage apparatus 14, the wedge 16, the collimator 17, the data acquisition circuitry 18, and/or the like. In addition, the rotating frame 13 may be configured to further support other various elements that are not illustrated in FIG. 15.

The X-ray high-voltage apparatus 14 includes: a high-voltage generating apparatus and an X-ray controlling apparatus. The high-voltage generating apparatus includes electrical circuitry such as a transformer and a rectifier or the like and is configured to generate the high voltage to be applied to the X-ray tube 11 and a filament current to be supplied to the X-ray tube 11. The X-ray controlling apparatus is configured to control output voltage corresponding to the X-rays to be emitted by the X-ray tube 11.

The high-voltage generating apparatus may be of a transformer type or an inverter type. Further, the X-ray high-voltage apparatus 14 may be provided on the rotating frame 13 in the gantry 10 or may be provided on a fixed frame (not illustrated) in the gantry 10. In this situation, the fixed frame is a frame configured to rotatably support the rotating frame 13.

The controlling apparatus 15 includes: a driving mechanism such as a motor and an actuator or the like; and processing circuitry which has a processor and a memory or the like configured to control the driving mechanism. The controlling apparatus 15 is configured to receive an input signal from an input interface 43 and/or an input interface provided in the gantry 10 and to control operations of the gantry 10 and the table 30.

Examples of the operation control exercised by the controlling apparatus 15 include: control to cause the rotating frame 13 to rotate, control to tilt the gantry 10, and control to bring the table 30 into operation. In this situation, the control to tilt the gantry 10 is realized as a result of the controlling apparatus 15 rotating the rotating frame 13 on an axis parallel to the X-axis direction, according to inclination angle (tilt angle) information input thereto through an input interface attached to the gantry 10.

Further, the controlling apparatus 15 may be provided for the gantry 10 or may be provided for the console 40. In this situation, the controlling apparatus 15 may be an example of a medical table controlling apparatus.

The wedge 16 is a filter for adjusting the amount of the X-rays emitted from the X-ray tube 11. More specifically, the wedge 16 is a filter configured to pass and attenuate the X-rays emitted from the X-ray tube 11 so that the X-rays emitted from the X-ray tube 11 onto the patient P have a predetermined distribution.

For example, the wedge 16 may be a wedge filter or a bow-tie filter and is configured by processing aluminum or the like so as to have a predetermined target angle and a predetermined thickness.

The collimator 17 is configured to limit a range of the emission of the X-rays that have passed through the wedge 16. The collimator 17 is configured to slidably support a plurality of lead plates blocking the X-rays and to adjust forms of slits formed by the plurality of lead plates. The collimator 17 may be referred to as an X-ray limiter.

The data acquisition circuitry 18 is configured to read, from the X-ray detector 12, the electrical signals corresponding to the amounts of X-rays detected by the X-ray detector 12. The data acquisition circuitry 18 is configured to acquire detection data having a digital value corresponding to the amounts of X-rays over a view period, by amplifying the read electrical signals and integrating (adding together) the electrical signals over the view period. The detection data may be referred to as projection data.

For example, the data acquisition circuitry 18 is realized by using an Application Specific Integrated Circuit (ASIC) having mounted thereon a circuitry element capable of generating the projection data. The projection data is transferred to the console 40 via a contactless data transfer apparatus or the like. The data acquisition circuitry 18 is an example of a detecting unit.

In this situation, the detection data generated by the data acquisition circuitry 18 is transmitted, via optical communication, from a transmitter provided on the rotating frame 13 and including a Light Emitting Diode (LED), to a receiver provided in a non-rotating part of the gantry 10 (e.g., the fixed frame; not illustrated in FIG. 15) and including a photodiode, so as to be further transferred to the console 40. The method for transmitting the detection data from the rotating frame 13 being a rotating part, to the non-rotating part of the gantry 10 is not limited to the optical communication described above. It is acceptable to adopt any method as long as the data is transferred in a contactless manner.

The table 30 is an apparatus configured to move the tabletop 33 into a hollow of the gantry 10, while the patient P to be scanned is placed thereon. The table 30 includes a base 31, a table driving apparatus 32, the tabletop 33, and a supporting frame 34. The base 31 is a casing configured to support the supporting frame 34 so as to be movable in vertical directions. The table driving apparatus 32 is a driving mechanism configured to move the tabletop 33 on which the patient P is placed, in the longitudinal directions of the tabletop 33. The table driving apparatus 32 includes a motor and an actuator, or the like.

The tabletop 33 is a board on which the patient P is placed. The tabletop 33 is provided on a top face of the supporting frame 34. The tabletop 33 is able to project from the table 30 toward the gantry 10 side (is able to move in the longitudinal direction), so as to make it possible to image the whole body of the patient P. For example, the tabletop 33 may be formed by using Carbon Fiber Reinforced Plastic (CFRP) having excellent X-ray transmittance and physical properties such as rigidity and strength. Further, the tabletop 33 may be hollow, for example.

The supporting frame 34 is configured to support the tabletop 33 so as to be movable in the longitudinal directions of the tabletop 33. Further, in addition to the tabletop 33, the table driving apparatus 32 may be configured to also move the supporting frame 34 in the longitudinal directions of the tabletop 33. The table 30 is an example of a medical table apparatus.

The console 40 includes a memory 41, a display 42, the input interface 43, and processing circuitry 44. Data communication among the memory 41, the display 42, the input interface 43, and the processing circuitry 44 is performed via a bus. Although the console 40 is described as being separate from the gantry 10, the gantry 10 may include the console 40 or one or more of the constituent elements of the console 40. The console 40 is an example of a medical table controlling apparatus.

For example, the memory 41 is realized by using a semiconductor memory element such as a Read-Only Memory (ROM), a Random Access Memory (RAM), or a flash memory, or a hard disk, an optical disk, or the like. Further, for example, the memory 41 is configured to store therein various types of programs. In this situation, a save region of the memory 41 may be within the X-ray computed tomography apparatus 1 or may be within an external storage apparatus connected via a network. The memory 41 is an example of a storage unit.

The display 42 is configured to display various types of information. For example, the display 42 is configured to display medical images (CT images) generated by the processing circuitry 44, a Graphical User Interface (GUI) used for receiving various types of operations from an operator, and the like. Information displayed by the display 42 includes notification information related to controlling the table according to the embodiment. As the display 42, it is possible to use various types of arbitrary displays, as appropriate.

For example, as the display 42, it is possible to use a Liquid Crystal Display (LCD), a Cathode Ray Tube (CRT) display, an Organic Electroluminescence Display (OELD), or a plasma display.

Further, the display 42 may be provided in any location in the control room. Also, the display 42 may be provided for the gantry 10. Furthermore, the display 42 may be of a desktop type or may be configured by using a tablet terminal or the like capable of wirelessly communicating with a main body of the console 40. In another example, as the display 42, one or more projectors may be used. The display 42 is an example of a display unit.

The input interface 43 is configured to receive various types of input operations from the operator, to convert the received input operations into electrical signals, and to output the electrical signals to the processing circuitry 44. For example, the input interface 43 is configured to receive, from the operator, an image taking condition, a reconstruction condition used at the time of reconstructing CT image data, an image processing condition for the CT image data, and the like.

As the input interface 43, it is possible to use, for example, a mouse, a keyboard, a trackball, a switch, a button, a joystick, a touchpad, a touch panel display, and/or the like, as appropriate.

In the present embodiment, the input interface 43 does not necessarily need to include those physical operation component parts. For instance, possible examples of the input interface 43 include electrical signal processing circuitry configured to receive an electrical signal corresponding to an input operation from an external input mechanism provided separately from the apparatus and to output the electrical signal to the processing circuitry 44.

Further, the input interface 43 may be provided for the gantry 10 and/or the table 30. Alternatively, the input interface 43 may be configured by using a tablet terminal or the like capable of wirelessly communicating with the main body of the console 40. The input interface 43 is an example of an input unit.

The processing circuitry 44 is configured to control operations of the entirety of the X-ray computed tomography apparatus 1. As hardware resources, the processing circuitry 44 includes a processor and a memory such as a ROM, a RAM, and/or the like. The processing circuitry 44 is configured to execute a system controlling function 441, an image generating function 442, an image processing function 443, a display controlling function 444, and the like, by employing the processor configured to execute programs loaded into the memory. The processing circuitry 44 is an example of a processing unit.

By employing the system controlling function 441, the processing circuitry 44 is configured to control various types of functions of the processing circuitry 44 on the basis of the input operations received from the operator via the input interface 43. For example, the processing circuitry 44 is configured to control positions of the tabletop 33 of the table 30. The processing circuitry 44 is configured to control a CT scan performed by the gantry 10. Further, the processing circuitry 44 is configured to obtain detection data acquired in the CT scan. In addition, the processing circuitry 44 may obtain detection data related to the patient P from the outside of the X-ray computed tomography apparatus 1.

By employing the image generating function 442, the processing circuitry 44 is configured to generate data by performing, on the detection data output from the data acquisition circuitry 18, pre-processing processes such as a logarithmic conversion process, an offset correction process, an inter-channel sensitivity correction process, a beam hardening correction, and/or the like. The processing circuitry 44 is configured to store the generated data into the memory 41.

Further, the data (the detection data) before the pre-processing processes and the data resulting from the pre-processing processes may collectively be referred to as projection data. The processing circuitry 44 is configured to generate the CT image data by performing a reconstructing process on the generated projection data (the projection data resulting from the pre-processing processes) by implementing a filtered backprojection method, a successive approximation reconstruction method, machine learning, or the like. The processing circuitry 44 is configured to store the generated CT image data into the memory 41.

By employing the image processing function 443, the processing circuitry 44 is configured to convert, by using a publicly-known method, the CT image data generated by the image generating function 442 into tomographic image data on an arbitrary cross-sectional plane or three-dimensional image data, on the basis of an input operation received from the operator via the input interface 43. For example, the processing circuitry 44 is configured to generate rendering image data in an arbitrary viewpoint direction, by applying, to the CT image data, a three-dimensional image processing process such as volume rendering, surface rendering, an image value projecting process, a Multi-Planar Reconstruction (MPR) process, or a Curved MPR (CPR) process.

Alternatively, the process of generating the three-dimensional image data such as the rendering image data in the arbitrary viewpoint direction, i.e., volume data, may directly be performed by the image generating function 442. The processing circuitry 44 is configured to store the tomographic image data or the three-dimensional image data into the memory 41.

By employing the display controlling function 444, the processing circuitry 44 is configured to cause the display 42 to display images, on the basis of various types of image data generated by the image processing function 443. Further, the images which the display 42 is caused to display include a CT image based on the CT image data, a cross-sectional image based on cross-sectional image data on an arbitrary cross-sectional plane, a rendering image in the arbitrary viewpoint direction based on the rendering image data in the arbitrary viewpoint direction, and the like. Further, the images which the display 42 is caused to display include an image for displaying an operation screen and an image for displaying a notification and an alert for the operator. The processing circuitry 44 realizing the display controlling function 444 is an example of a display controlling unit.

The functions 441 to 444 do not necessarily need to be realized by the single piece of processing circuitry. It is also acceptable to structure the processing circuitry 44 by combining together a plurality of independent processors, so that the functions 441 to 444 are realized as a result of the processors executing programs. The functions 441 to 444 may be realized as being distributed among or integrated into one or more pieces of processing circuitry, as appropriate.

Further, although the console 40 was described as a single console configured to execute the plurality of functions, it is also acceptable to configure separate consoles to execute the plurality of functions. For example, the functions of the processing circuitry 44 such as the image generating function 442 and the image processing function 443 may be provided in a distributed manner.

Further, a part or all of the processing circuitry 44 not only may be included in the console 40, but also may be included in a consolidated server configured to collectively perform a process on detection data acquired by a plurality of medical image diagnosis apparatuses.

Further, one or both of a post-processing process and a display process may be performed either by the console 40 or an external workstation. Further, the console 40 and the workstation may perform one or both of those processes at the same time. For example, as the workstation, it is possible to use, as appropriate, a computer or the like including a processor configured to realize functions corresponding to the processes and a memory such as a ROM, a RAM, and/or the like, as hardware resource.

The term “processor” used in the above description denotes, for example, a Central Processing Unit (CPU), a Graphics Processing Unit (GPU), or circuitry such as an ASIC or a programmable logic device (PLD). Examples of the PLD include a Simple Programmable Logic Device (SPLD), a Complex Programmable Logic Device (CPLD), and a Field Programmable Gate Array (FPGA). One or more processors are configured to realize the functions by reading and executing the programs saved in storage circuitry. The storage circuitry having the programs saved therein is a non-transitory computer-readable recording medium.

Further, instead of having the programs saved in the storage circuitry, it is also acceptable to directly incorporate the programs in the circuitry of the one or more processors. In that situation, the one or more processors are configured to realize the functions by reading and executing the programs incorporated in the circuitry thereof. In another example, instead of executing the programs, it is also acceptable to realize the functions corresponding to the programs, by using a combination of logical circuitry. Further, the processors in the present embodiments do not each necessarily have to be structured as a single piece of circuitry. It is also acceptable to structure one processor by combining together a plurality of pieces of independent circuitry so as to realize the functions thereof. Further, it is also acceptable to integrate two or more of the constituent elements depicted in FIG. 15 into one processor, so as to realize the functions thereof.

To the reconstruction of the X-ray CT image data, it is possible to apply a reconstruction scheme such as a full-scan reconstruction scheme or a half-scan reconstruction scheme. For example, by employing the image generating function 442, the processing circuitry 44 is configured to use projection data from an entire circle around the patient P corresponding to 360 degrees, when the full-scan reconstruction scheme is used. In contrast, the processing circuitry 44 is configured to use projection data corresponding to “180 degrees+a fan angle”, when the half-scan reconstruction scheme is used. In the following sections, for the sake of convenience in the explanations, it is assumed that the processing circuitry 44 is configured to adopt the full-scan reconstruction scheme by which the reconstruction is performed while using the projection data from an entire circle around the patient P corresponding to 360 degrees.

The techniques described in the present embodiments are applicable both to a single-tube X-ray computed tomography apparatus and to a so-called multi-tube X-ray computed tomography apparatus in which a plurality of pairs each made up of an X-ray tube and a detector are mounted on a rotating ring.

Further, the techniques described in the present embodiments are also applicable to an X-ray computed tomography apparatus 1 configured to perform imaging by using a dual-energy scheme. In that situation, the X-ray high-voltage apparatus 14 is capable of alternately switching between energy spectra of the X-rays emitted from the X-ray tube 11, through a fast switching process between two voltage values, for example. In other words, the X-ray computed tomography apparatus 1 is configured to be able to acquire projection data in different acquisition views, while modulating X-ray tube voltage with timing corresponding to control signals for modulating the X-ray tube voltage. By imaging the patient P while using the mutually-different levels of X-ray tube voltage, it is possible to enhance dark/light contrast in the CT images, on the basis of energy transmittance of substances corresponding to each of the energy spectra of the X-rays.

Further, it is assumed that the X-ray computed tomography apparatus 1 according to the present embodiments is configured to read the electrical signals from the X-ray detector 12 by using a sequential reading scheme.

Further, it is also acceptable to configure the X-ray computed tomography apparatus 1 according to the present embodiments as a movable CT apparatus in which the gantry 10 and the table 30 are movable.

Furthermore, although the table control in the present embodiments is, for example, realized by the console 40 of the X-ray computed tomography apparatus 1, alternatively the table control may be realized by the controlling apparatus 15 or may be realized by a computer installed on the gantry 10 or the table 30.

For example, there are various types of X-ray computed tomography apparatuses such as third generation Computed Tomography (CT) and fourth generation CT apparatuses. The present embodiments are applicable to any type. The third generation CT denotes a Rotate/Rotate-type in which an X-ray tube and a detector integrally rotate around a patient. The fourth generation CT denotes a Stationary/Rotate-type in which a large number of X-ray detecting elements are fixed while being arrayed in a ring formation, so that only an X-ray tube rotates around a patient.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor apparatus comprising:
a substrate;
a wiring layer serving as a topmost layer formed over the substrate;
a first protection film formed so as to cover the wiring layer;
a planarization film formed on the first protection film; and
a second protection film formed on the planarization film, wherein
the first protection film and the second protection film are each thicker than the planarization film.

2. The semiconductor apparatus according to claim 1, wherein
each of the first protection film and the second protection film is a silicon oxynitride film or a silicon nitride film, and
a thickness of each of the first protection film and the second protection film is in a range from 420 nm to 700 nm.

3. The semiconductor apparatus according to claim 1, wherein
the planarization film is a silicon oxide film, and
a thickness of the planarization film is in a range from 100 nm to 400 nm.

4. The semiconductor apparatus according to claim 2, wherein an organic film is formed on the second protection film.

5. The semiconductor apparatus according to claim 4, wherein a thickness of the organic film is in a range from 1 μm to 3 μm.

6. The semiconductor apparatus according to claim 4, wherein
an optical clear adhesive sheet is the second protection film or the organic film, and
a scintillator is provided on the optical clear adhesive sheet.

7. A semiconductor apparatus manufacturing method comprising:
forming a wiring layer over a semiconductor substrate;
forming a first protection film on the wiring layer serving as a topmost layer;
forming a planarization film on the first protection film; and
forming a second protection film on the planarization film, wherein
each of the first protection film and the second protection film is a silicon nitride film or a silicon oxynitride film formed to have a thickness in a range from 420 nm to 700 nm, and
the planarization film is a silicon oxide film formed to have a thickness in a range from 100 nm to 400 nm.

8. The semiconductor apparatus manufacturing method according to claim 7, comprising:
forming an organic film on the second protection film, wherein
the organic film is formed to have a thickness in a range from 1 μm to 3 μm.

9. The semiconductor apparatus manufacturing method according to claim 7, comprising:
providing each of an optical clear adhesive sheet and a scintillator being the second protection film or an organic film formed on the second protection film.

10. The semiconductor apparatus manufacturing method according to claim 8, comprising:
providing each of an optical clear adhesive sheet and a scintillator being the second protection film or the organic film formed on the second protection film.

11. The semiconductor apparatus manufacturing method according to claim 9, wherein, prior to the providing of the optical clear adhesive sheet and the scintillator, one of the second protection film and the organic film comes under pressure.

12. The semiconductor apparatus manufacturing method according to claim 10, wherein, prior to the providing of the optical clear adhesive sheet and the scintillator, one of the second protection film and the organic film comes under pressure.

13. An X-ray computed tomography apparatus including an X-ray tube configured to emit X-rays and an X-ray detector configured to detect the X-rays emitted by the X-ray tube, wherein
the X-ray detector comprises:
a substrate;
a wiring layer serving as a topmost layer formed over the substrate;
a first protection film formed so as to cover the wiring layer;
a planarization film formed on the first protection film; and
a second protection film formed on the planarization film, and
the first protection film and the second protection film are each thicker than the planarization film.
